(19) United States
(12) Patent Application Publication
(10) Pub. No.: US 2015/0028914 A1
(43) Pub. Date: Jan. 29, 2015

(54) SEMICONDUCTOR DEVICE AND METHOD FOR FORMING THE SAME

(71) Applicant: SK HYNIX INC., Icheon (KR)

(72) Inventor: Young Soo KIM, Icheon (KR)

(73) Assignee: SK HYNIX INC., Icheon (KR)

(21) Appl. No.: 14/167,863

(22) Filed: Jan. 29, 2014

(30) Foreign Application Priority Data
Jul. 24, 2013 (KR) 10-2013-0087137

(51) Int. Cl. H01L 23/48; G01R 31/26

(52) U.S. Cl. CPC H01L 23/481; G01R 31/26
USPC 324/762.01; 257/774

(57) ABSTRACT

A semiconductor device includes a through silicon via (TSV) formed in a semiconductor substrate including a first-type impurity; and a first doping region formed in the semiconductor substrate located below the TSV. The first doping region is configured to include a second-type impurity and selectively electrically coupled to the TSV.

### CROSS-REFERENCE TO RELATED APPLICATION

The priority of Korean patent application No. 10-2013-0087137, filed on 24 Jul. 2013, the disclosure of which is hereby incorporated by reference in its entirety, is claimed.

### BACKGROUND

A packaging technology of an integrated circuit (IC) has been continuously developed to satisfy the demand for miniaturization and mounting reliability. In recent years, various stack technologies have been developed to meet the demand for high performance in addition to the demand for miniaturization of electric/electronic products.

A stack package formed by stacking individual semiconductor chips has been manufactured by simultaneously packaging the stacked semiconductor chips and stacking the packaged semiconductor chips. The individual semiconductor chips of the stack package are electrically coupled through a metal wire, a through silicon via (TSV), or the like. Specifically, a stack package including a through silicon via (TSV) is configured to form a through silicon via (TSV) in a semiconductor chip, such that physical and electrical connection is vertically formed among semiconductor chips by the TSV. The stack package including the TSV interfaces signals, power supply, etc. through the TSV so as to minimize power or current consumption and signal delay, resulting in superior operation throughput or performance due to an improved bandwidth.

### SUMMARY

Various embodiments are directed to providing a semiconductor device and a method for forming the same to address issues arising in the related art.

Embodiments relate to a semiconductor device including a through silicon via (TSV) and a method for forming the same.

In accordance with one aspect of the embodiment, a semiconductor device includes: a through silicon via (TSV) formed in a semiconductor substrate including a first-type impurity; and a first doping region formed in the semiconductor substrate below the TSV, wherein the first doping region is doped with a second-type impurity and is configured to be selectively electrically coupled to the TSV.

The first-type impurity includes P-type impurity.

The second-type impurity includes N-type impurity.

A second doping region including the first-type impurity and configured to be electrically isolated from the TSV.

A power-supply circuit coupled to the second doping region.

A test circuit coupled to the TSV so as to be applied to a current or voltage through the TSV.

A data memory element electrically coupled to the TSV.

The data memory element includes at least one of a capacitor, a floating gate, a resistance variation element, a magnetic variation element, a data processing element electrically coupled to the TSV. the data processing element includes at least one of a central processing unit (CPU), a graphic processing unit, a digital signal processing (DSP) unit, and an electronic element capable of processing other data.

In accordance with another aspect of the embodiment, a method for detecting a defective part of a semiconductor device includes: providing a power-supply circuit; applying a current or voltage from the power-supply circuit to a test circuit through a PN junction and a through silicon via (TSV) in a semiconductor substrate; applying the current or voltage to a gate of the test circuit; and monitoring a current or voltage flowing toward a ground voltage (VSS) terminal.

The PN junction includes a first doping region and a second doping region.

The first doping region includes N-type impurity.

The first doping region includes N-type polysilicon.

The second doping region includes P-type impurity.

The second doping region includes P-type polysilicon.

The first doping region is formed below the TSV.

The power-supply circuit is coupled to the second doping region.

A data memory element electrically coupled to the TSV.

The data memory element includes at least one of a capacitor, a floating gate, a resistance variation element, a magnetic variation element, and an electronic element capable of storing other data.

A data processing element electrically coupled to the TSV. the data processing element comprises at least one of a central processing unit (CPU), a graphic processing unit, a digital signal processing (DSP) unit, and an electronic element capable of processing other data.

In accordance with another aspect of the embodiment, a method for detecting a defective part of a semiconductor device includes: providing a first terminal, a semiconductor substrate, a PN junction, a through-silicon-via (TSV), a test mode control transistor, and a second terminal serially coupled; applying a first bias to the PN junction so that current flows from the semiconductor substrate through the TSV to the second terminal; and detecting current between the TSV and the second terminal.

The applying the first bias includes: applying a first voltage to the semiconductor substrate through the first terminal, applying a second voltage to the second terminal and turning on the test mode control transistor by applying a third voltage to a gate of the test mode control transistor.

A doping region is formed between the semiconductor substrate and the through-silicon-via (TSV), and wherein the PN junction is formed at an interface between the semiconductor substrate and the doping region.

The first bias is a forward bias; the first voltage is a power supply voltage; and the second voltage is a ground voltage.

The current is detected between the test mode control transistor and the second terminal.

The current is detected between the TSV and the test mode control transistor.

In accordance with another aspect of the embodiment, a semiconductor device includes: a through-silicon-via (TSV) provided in a semiconductor substrate; a PN junction provided between the through-silicon-via (TSV) and the semiconductor substrate; and a test mode control transistor configured to control the PN junction.

A test mode control transistor configured to: in a test mode, apply a forward bias to the PN junction, and in a non-test mode, apply a reverse bias to the PN junction.

A first terminal coupled to the semiconductor substrate, and a second terminal coupled to the TSV, wherein the test mode control transistor is serially coupled between the TSV and the second terminal.

In the test mode: a power supply voltage is applied to the first terminal, and a ground voltage is applied to the second terminal.

It is to be understood that both the foregoing general description and the following detailed description of the embodiments are exemplary and explanatory.

### BRIEF DESCRIPTION OF THE DRAWINGS

FIGS. 1a to 1f are cross-sectional views illustrating a semiconductor device according to an embodiment.

FIG. 2 is a block diagram illustrating a microprocessor according to an embodiment.

FIG. 3 is a block diagram illustrating a processor according to an embodiment.

FIG. 4 is a block diagram illustrating a system according to an embodiment.

FIG. 5 is a block diagram illustrating a data storage system according to an embodiment.

FIG. 6 is a block diagram illustrating a memory system according to an embodiment.

### DESCRIPTION OF EMBODIMENTS

Reference will now be made in detail to certain embodiments, examples of which are illustrated in the accompanying drawings. Wherever possible, the same reference numbers will be used throughout the drawings to refer to the same or like parts. A semiconductor device and a method for forming the same according to embodiments will hereinafter be described with reference to the appended drawings.

The following embodiment will exemplarily disclose a semiconductor device including a single through silicon via (TSV) for convenience of description and better understanding of the embodiment. However, the number of TSV is not limited to one or any other particular number. The term “through silicon via (TSV)” may also be referred to herein as “through electrode” or “through substrate via”.

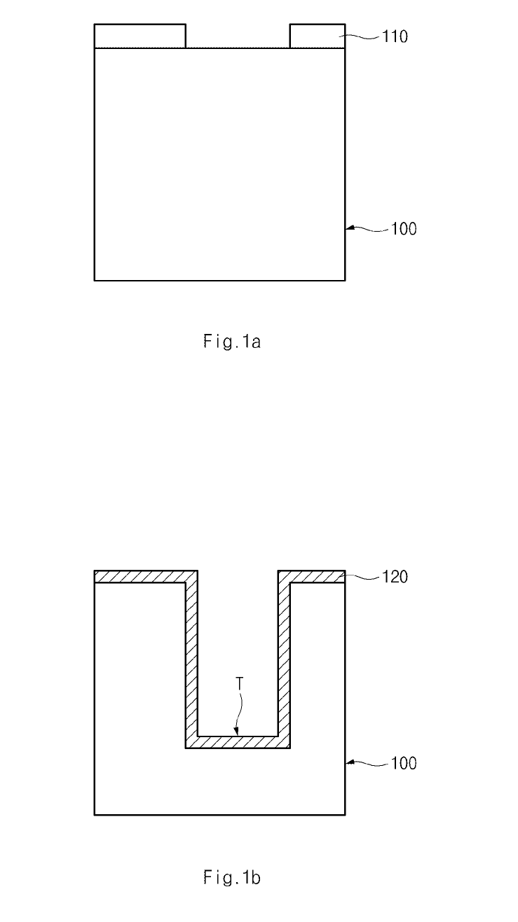

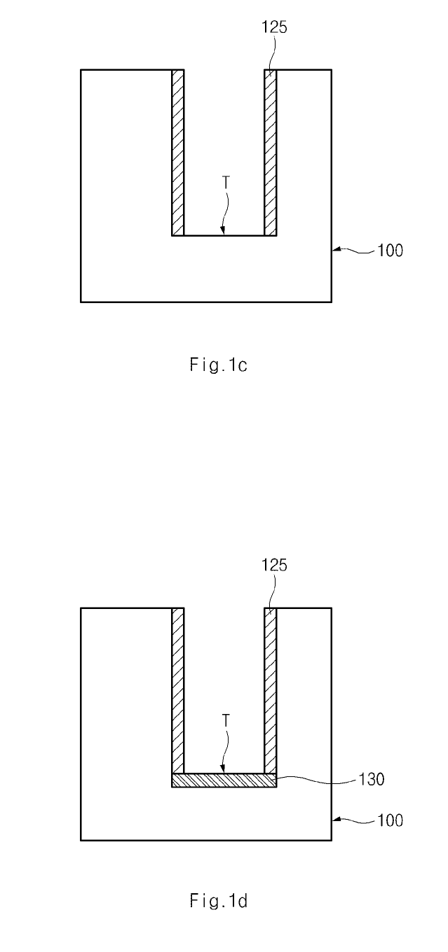

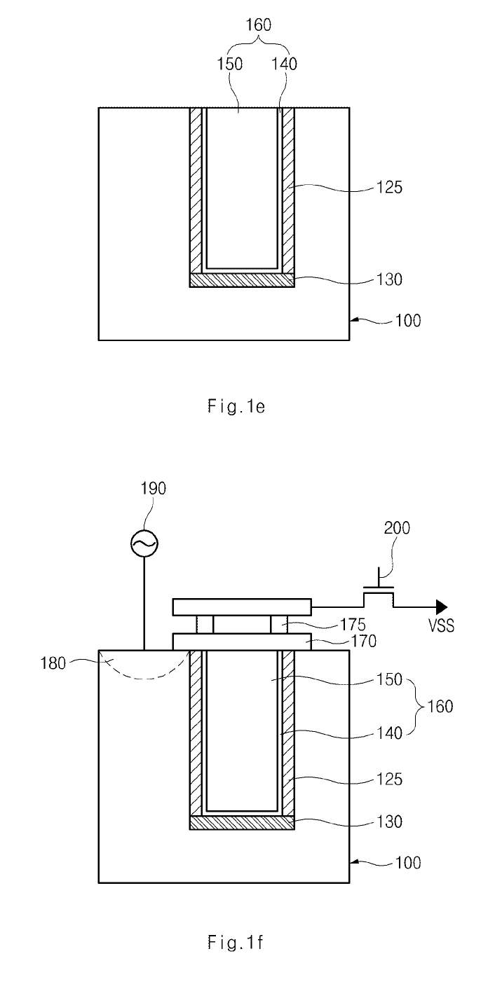

FIGS. 1a to 1f are cross-sectional views illustrating a semiconductor device according to an embodiment. The semiconductor device according to the embodiment exemplarily includes a via middle structure for convenience of description. However, a via-first structure can be manufactured by the same fabrication process.

Referring to FIG. 1a, a mask pattern 110 configured to define a trench is formed over a semiconductor substrate 100 including a first-type impurity. In this case, the first-type impurity is a P-type impurity.

Referring to FIG. 1b, the semiconductor substrate 100 is etched using the mask pattern 110 as a mask so as to form a trench T. In this case, the trench T may define a TSV formation region.

An insulation film 120 is formed over the trench T and the semiconductor substrate 100. The insulation film 120 may be formed of a High Density Plasma (HDP) oxide film, a Boron Phosphorus Silicate Glass (BPSG) film, a Phosphorus Silicate Glass (PSG) film, a Boron Silicate Glass (BSG) film, a Tetra Ethyle Ortho Silicate (TEOS) film, an Undoped Silicate Glass (USG), or a combination thereof. The insulation film 120 may insulate the semiconductor substrate 100 and the TSV, and may reduce capacitance.

Referring to FIG. 1c, the insulation film 120 is etched back or anisotropically etched to expose a lower portion of the trench T, such that an insulation film pattern 125 is formed only at a sidewall of the trench T. In this case, for etching the insulation film 120, a dry etch method may be used.

Referring to FIG. 1d, after a second-type impurity is ion-implanted into the semiconductor substrate 100 exposed by the trench T, an annealing process is performed at a predetermined temperature so as to form a first doping region 130. Here, the second-type impurity may be an N-type impurity.

As a result, a PN junction (diode) may be formed between the P-type semiconductor substrate 100 and the first doping region 130. In this case, when the semiconductor substrate 100 is an N-type substrate, P-type impurity is ion-implanted to form a P-type doped region, resulting in formation of a PN junction. The P-type doped region may be replaced with a doped poly material such as P-type polysilicon, instead of ion implantation. In addition, the first doping region 130 may be replaced with a poly material such as N-type polysilicon, instead of implantation.

Referring to FIG. 1e, a barrier metal 140 is deposited over a surface of the trench T. Then, a TSV electrode material 150 is deposited over the barrier metal 140.

Thereafter, the TSV electrode material 150 and the barrier metal 140 are CMP-etched until the semiconductor substrate 100 is exposed, such that a through silicon via (TSV) 160 is completed. In this case, the barrier metal 140 may be formed of a stacked structure of a titanium (Ti) film and a titanium nitride (TiN) film, and may also be formed of the titanium (Ti) film or the titanium nitride (TiN) film. In addition, the TSV electrode material 150 may interface signals, power supply, etc., and may be formed of a high-conductivity metal, for example, copper (Cu), tantalum (Ta), etc.

Referring to FIG. 1f, a pad 170 is stacked over the through silicon via (TSV) 160. In this case, a method for forming the pad 170 is similar to a conventional method. Thus, a detailed description thereof will herein be omitted for convenience of description. In this case, the pad 170 may also be referred to as a TSV pad or a TSV pad. A metal line 175 configured to interconnect a plurality of pads 170 may be additionally formed between the pads 170.

Thereafter, the P-type impurity is doped on the semiconductor substrate 100 so that a second doping region 180 can be formed. In this case, the second doping region 180 may be doped with a high-density P-type impurity, and may be electrically isolated the TSV 160. The second doping region 180 may be coupled to a power-supply circuit 190 for providing a power-supply voltage.

A current or voltage received from the power-supply circuit 190 is applied to the TSV 160, the pad 170, and the metal line 175 through a PN junction between the second doping region 180 and the first doping region 130, and flows out to a ground voltage (VSS) through a test circuit 200. The test circuit 200 may include an NMOS transistor 200. A high voltage is applied to a gate control signal of the test circuit 200 through the TSV 160, such that it may measure a current or voltage flowing to the ground voltage (VSS) terminal.

In addition, a data memory device and data processing devices may be electrically coupled to the TSV 160, in addition to the pad 170 and the metal line 175.

For example, the data memory device may include a capacitor, a floating gate, a resistance variation element, a magnetic variation element, an electronic element capable of storing other data, or a combination thereof. The data processing element may include a central processing unit (CPU), a graphic processing unit, a digital signal processing (DSP) unit, an electronic element capable of processing other data, or a semiconductor device formed of a combination thereof. For example, the semiconductor device may include the CPU, the graphic processing unit, the digital signal processing (DSP) unit, and the electronic element.

In addition, a method for detecting a defective part such as a void contained in the TSV 160 applies a positive (+) voltage to the power-supply circuit 190, and applies a high voltage to a gate control signal of the test circuit 200 through the PN junction and the TSV 160, such that it can monitor a current flowing to the ground voltage (VSS) terminal and at the same time can detect the presence or absence of a defective or faulty part.

In a general chip operation mode, a current is prevented from flowing from the substrate 100 to the TSV 160 because a reverse junction is formed between the substrate 100 to the TSV 160. In contrast, in a test mode for testing presence or absence of a defect of the TSV 160, a current can flow through the PN junction because a forward junction is formed. Thus, it may be possible to detect a defect such as a void contained in the TSV 160.

In accordance with an aspect of the embodiment, a semiconductor device includes: a through-silicon-via (TSV) provided in a semiconductor substrate; a PN junction provided between the through-silicon-via (TSV) and the semiconductor substrate; and a test mode control transistor configured to control the PN junction.

A test mode control transistor configured to: in a test mode, apply a forward bias to the PN junction, and in a non-test mode, apply a reverse bias to the PN junction.

A first terminal coupled to the semiconductor substrate, and a second terminal coupled to the TSV, wherein the test mode control transistor is serially coupled between the TSV and the second terminal.

In the test mode: a power supply voltage is applied to the first terminal, and a ground voltage is applied to the second terminal.

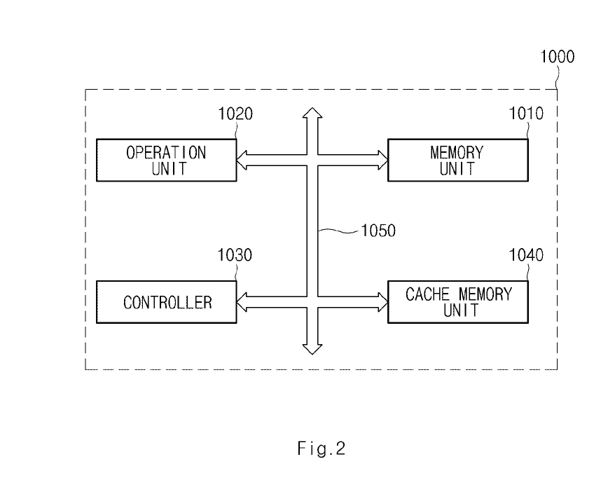

FIG. 2 is a block diagram illustrating a microprocessor 1000 according to an embodiment.

Referring to FIG. 2, the microprocessor 1000 may be configured to control and adjust a series of operations for receiving data or signals, process the data or signals, and outputting the processed result, and may include a memory unit 1010, an operation unit 1020, and a controller 1030. Each unit may include logic elements, for example, various transistors formed over the semiconductor substrate, gates coupled to the transistors, flip-flops, etc. The microprocessor 1000 may include a variety of data processors, for example, a Central Processing Unit (CPU), a Graphic Processing Unit (GPU), a Digital Signal Processor (DSP), an Application Processor (AP), etc.

The memory unit 1010 serving as a processor register or a register may include a variety of registers such as a data register, an address register, and a floating-point register. The memory unit 1010 may temporarily store either data for calculation of the operation unit 1020 or execution resultant data, and may store an address in which data for execution is stored.

The operation unit 1020 is configured to perform internal operation of the microprocessor 1000, and performs various four fundamental arithmetic operations or a logic operation according to results obtained by command interpretation of the controller 1030. The operation unit 1020 may include one or more Arithmetic and Logic Units (ALUs).

The controller 1030 may receive signals from the memory unit 1010, the operation unit 1020, the microprocessor 1000, and other external devices, and may perform various control operations such as command extraction, command analysis, and command input/output, etc. such that processes written by programming can be carried out.

The microprocessor 1000 may include a through silicon via (TSV) to allow the units 1010, 1020, 1030, 1040 to communicate with each other or with various external devices at a high speed. For example, the TSV may be directly or indirectly coupled to the controller 1030, the memory unit 1010, and the operation unit 1020. The TSV structure may include an embodiment described above. For example, the TSV structure may include a TSV formed in a semiconductor substrate including a first-type impurity; and a first doping region including a second-type impurity, formed in the semiconductor substrate located below the TSV, and electrically coupled to the TSV. The microprocessor 1000 according to an embodiment includes a PN junction (diode) formed by the first doping region and the semiconductor substrate. As a result, an electric path between the semiconductor substrate and the TSV is inactivated during a normal operation. In contrast, in a test mode, the current path between the semiconductor substrate and the TSV is activated through a PN junction. Thus, presence or absence of a defect in the TSV structure can be detected. The defect may include a void in the TSV, thereby providing a microprocessor 1000 having increased reliability.

The microprocessor 1000 according to the embodiment may further include a cache memory unit 1040 for receiving data from an external device, temporarily storing the data, and transmitting to another external device. In this case, the memory unit 1010, the operation unit 1020, the controller 1030, and the cache memory unit 1040 may communicate with each other through a bus interface 1050. In addition, the cache memory unit 1040 may be electrically coupled to the TSV.

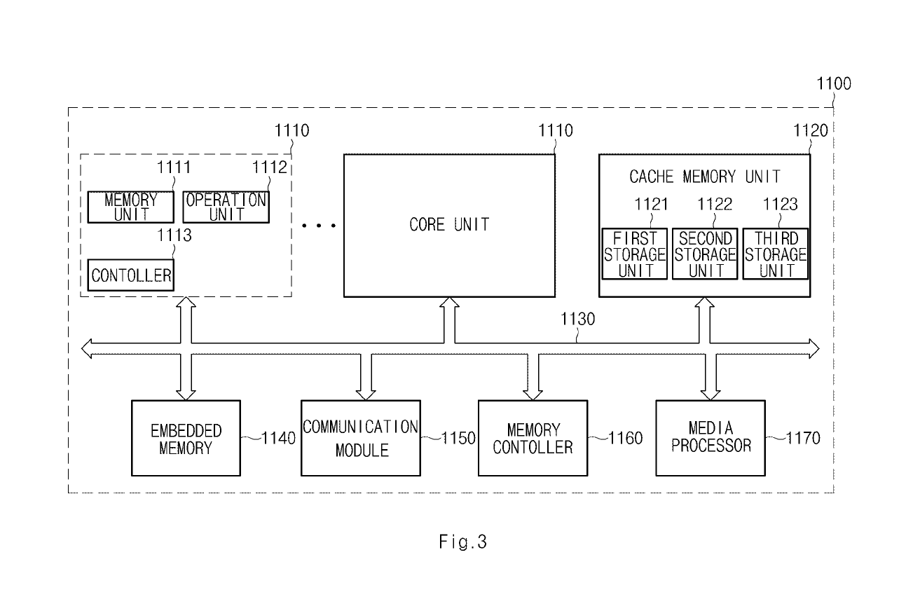

FIG. 3 is a block diagram illustrating a processor 1100 according to an embodiment.

Referring to FIG. 3, the processor 1100 may include various logic elements, for example, transistors formed over a semiconductor substrate, gates coupled to the transistors, flip-flops, etc. The processor 1100 may include a microprocessor configured to control and adjust a series of operations for receiving data from various external devices and outputting the processed result to various external devices, and may include a variety of functions, such that throughput improvement and multi-functional characteristics can be implemented. The processor 1100 may include a core unit 1110 serving as a microprocessor, a cache memory unit 1120 for temporarily storing data, and a bus interface 1130 for data communication between internal and external devices. The processor 1100 may be a variety of system on chips (SoCs) such as a Multi Core Processor (MCU), a Graphic Processing Unit (GPU), an Application Processor (AP), etc.

The core unit 1110 according to the embodiment is used as an arithmetic/logic operator which processes data received from an external device, and may include a memory unit 1111, an operation unit 1112, and a controller 1113. The memory unit 1111 may function as a processor register or a register. The memory unit 1111 in the processor 1110 stores data, may include a variety of registers such as a data register, an address register, a floating-point register, etc. The memory unit 1111 may temporarily store either data for calculation in the operation unit 1112 or execution resultant data, and may store an address in which data for execution is stored. The operation unit 1112 is configured to perform internal operation, and performs various four fundamental arithmetic operations or a logic operation according to the result obtained by command interpretation of the controller 1113. The operation unit 1112 may include one or more Arithmetic and Logic Units (ALUs). The controller 1113 may receive signals from the memory unit 11111, the operation unit 1112, the processor 1110, or other external devices, and may perform various control operations such as command extraction, command analysis, and command input/output, etc. such that processes written by programming can be carried out.

Unlike the core unit 1110 operating at a high speed, the cache memory unit 1120 may temporarily store data to compensate a difference in data processing speeds between the core unit 1110 and a low-speed external device, and may include a first storage unit 1121, a second storage unit 1122, and a third storage unit 1123. The number of storage unit varies depending on required memory capacity. For example, a typical cache memory unit 1120 may include the first storage unit 1121 and the second storage unit 1122. If the cache memory unit 1120 needs to have high capacity, it may further include the third storage unit 1123. If necessary, however, the cache memory unit 1120 may further many more storage units. That is, the number of storage units contained in the cache memory unit 1120 may be differently adjusted according to a variety of designs. The first, second, and third storage units (1121, 1122, 1123) may be the same or different in data storage capacity or in processing speeds. For example, the first to third storage units (1121, 1122, 1123) have different processing speeds, and the first storage unit 1121 may have the highest speed.

Although the first, second, and third storage units (1121, 1122, 1123) are built in the cache memory unit 1120 as shown in FIG. 3, the first to third storage units (1121, 1122, 1123) of the cache memory unit 1120 may be provided outside of the core unit 1110, making possible to compensate a difference in processing speed between the core unit 1110 and the external device. Alternatively, the first storage unit 1121 of the cache memory unit 1120 may be provided inside of the core unit 1110, and the second and third storage units (1122, 1123) may be provided outside of the core unit 1110. In another instance, the first storage unit 1121 and the second storage unit 1122 of the cache memory unit 1120 may be provided inside the core unit 1110, and the third storage unit 1123 may be provided outside the core unit 1110.

A bus interface 1130 may couple the core unit 1110 to the cache memory unit 1120, such that data can be more efficiently transmitted through the bus interface 1130.

The processor 1100 according to the embodiment may include a plurality of core units 1110. The plurality of core units 1110 may share the cache memory unit 1120. The core units 1110 may be coupled to the cache memory unit 1120 through the bus interface 1130. The plurality of core units 1110 may be identical to each other in structure. When the processor 1100 includes a plurality of core units 1110, a plurality of first storage unit 1121 are provided inside of the cache memory unit 1120 so that respective first storage units 1121 may be in correspondence to the respective core units 1110. The second storage unit 1122 and the third storage unit 1123 may be integrated into a single storage unit, and the integrated storage unit may be provided outside the plurality of core units 1110 and be shared by a bus interface 1130. Here, the processing speed of the first storage unit 1121 may be higher than that of the second or third storage unit 1122 or 1123. In another instance, the first storage unit 1121 and the second storage unit 1122 may be provided in respective core units 1110, the third storage unit 1123 may be provided outside the plurality of core units 1110 and be shared by the bus interface 1130.

The processor 1100 according to the embodiment may further include an embedded memory 1140 for storing data; a communication module 1150 for transmitting/receiving data to/from an external device by wire or wirelessly; a memory controller 1160 for driving an external memory device; and a media processor 1170 for processing either data processed by the processor 1100 or input data received from the external input device, and outputting the processed data to the external interface device. Besides the above constituent elements, the processor 1100 may further include a plurality of modules or devices. In this case, the added modules may transmit/receive data to/from the core unit 1110 and the cache memory 1120 through the bus interface 1130.

The embedded memory 1140 may include a non-volatile memory or a volatile memory. The volatile memory may include a Dynamic Random Access Memory (DRAM), a Mobile DRAM, a Static Random Access Memory (SRAM), and the like. The non-volatile memory may include a Read Only Memory (ROM), a Nor Flash Memory, a NAND Flash Memory, a Phase Change Random Access Memory (PRAM), a Resistive Random Access Memory (RRAM), a Spin Transfer Torque Random Access Memory (STTRAM), a Magnetic Random Access Memory (MRAM), and the like.

The communication module 1150 may include a module coupled to a wired network and a module coupled to a wireless network. The wired network module may include a Local Area Network (LAN), a Universal Serial Bus (USB), an Ethernet, a Power Line Communication (PLC), etc. The wireless network module may include a variety of devices for data communication without using a transfer line. For example, the wireless network module may include Infrared Data Association (IrDA), Code Division Multiple Access (CDMA), Time Division Multiple Access (TDMA), Frequency Division Multiple Access (FDMA), Wireless LAN (WLAN), Zigbee, Ubiquitous Sensor Network (USN), Bluetooth, Radio Frequency Identification (RFID), Long Term Evolution (LTE), Near Field Communication (NFC), Wireless Broadband Internet (Wibro), High Speed Downlink Packet Access (HSDPA), Wideband CDMA (WCDMA), Ultra WideBand (UWB), etc.

The memory controller 1160 may control data transmission between the processor 1100 and external storage devices operated according to different communication standards, and may include a variety of memory controllers and a controller. Here, the controller may control Integrated Device Electronics (IDE), Serial Advanced Technology Attachment (SATA), Small Computer System Interface (SCSI), Redundant Array of Independent Disks (RAID), Solid State Disc (SSD), External SATA (eSATA), Personal Computer Memory Card International Association (PCMCIA), Universal Serial Bus (USB), Secure Digital (SD), mini Secure Digital card (mSD), micro SD, Secure Digital High Capacity (SDHC), Memory Stick Card, Smart Media Card (SM), Multi Media Card (MMC), Embedded MMC (eMMC), Compact Flash (CF), etc.

The media processor 1170 may include a Graphics Processing Unit (GPU), a Digital Signal Processor (DSP), a High Definition Audio (HD Audio), a High Definition Multimedia Interface (HDMI) controller, etc., and is configured to receive data from an external input device, process the data in the form of audio, video, etc., and transmit the processed data to an external interface device.

The processor 1100 may include a through silicon via (TSV). TSV is formed over a semiconductor substrate so as to permit communication between various devices at high speed. The various devices may have different structures and include the core unit 1110, the cache memory unit 1120, the bus interface 1130, etc. The processor 1100 may include a plurality of TSVs. By employing TSVs, the core unit 1110, the cache memory unit 1120, the bus interface 1130, etc may be directly or indirectly coupled to each other.

The TSV structure may be formed in a semiconductor substrate. The semiconductor substrate includes a first-type impurity. A first doping region including a second-type impurity is formed in the semiconductor substrate and below the TSV, and electrically coupled to the TSV.

The processor 1100 according to the embodiment includes a PN junction (diode) formed by the first doping region and the semiconductor substrate. As a result, the processor 1100 is configured to block an electric path between the TSV and the semiconductor substrate during a normal operation. The processor is further configured to activate the current path through a PN junction in a test mode during which presence or absence of a defect in the TSV structure is tested. The defect may include the presence of a void in the TSV. Utilizing such a test, reliability of the microprocessor 1100 can be increased. The processor 1100 may include a plurality of TSVs. By employing TSVs, various structures such as the core unit 1110, the cache memory unit 1120, the bus interface 1130, etc. may be directly or indirectly coupled to each other.

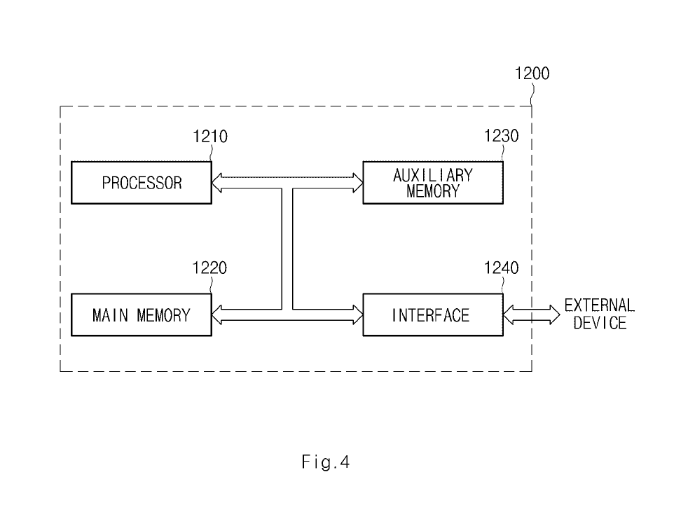

FIG. 4 is a block diagram illustrating a system 1200 according to an embodiment.

Referring to FIG. 4, the system 1200 serving as a data processor may perform a variety of operations such as input, processing, output, communication, and storing actions, and may include a processor 1210, a main memory unit 1220, an auxiliary memory unit 1230, and an interface unit 1240. The system according to the embodiment may be any one of a variety of electronic systems operated by a variety of processes, for example, a computer, a server, a Personal Digital Assistant (PDA), a Portable Computer, a Web Tablet, a Wireless Phone, a mobile phone, a smart phone, a digital music player, Portable Multimedia Player (PMP), a camera, a Global Positioning System (GPS), a video camera, a voice recorder, a Telematics, an Audio Visual (AV) System, a Smart Television, etc.

The processor 1210 may interpret a command stored therein and a command received from an external part, may perform various processes such as calculation, comparison, etc. of external input data transmitted to the system 1200, and data stored in the main memory unit 1220 or the auxiliary memory unit 1230. The processor 1210 may include various core elements of the system, for example, a Micro Processor Unit (MPU), a Central Processing Unit (CPU), a Single/Multi Core Processor, a Graphic Processing Unit (GPU), an Application Processor (AP), a Digital Signal Processor (DSP), etc. The processor 1210 may include various logic elements, for example, transistors formed over a semiconductor substrate, gates coupled to the transistors flip-flops, etc.

The main memory unit 1220 may temporarily store or shift program codes or data received from the auxiliary memory device 1230, such that it can execute the program corresponding to the stored or shifted codes or data. The main memory unit 1220 may include the semiconductor device according to the embodiment. The main memory unit 1220 may include various volatile memory units contents (data) stored in which is deleted when power is off, for example, Static Random Access Memory (SRAM), a Dynamic Random Access Memory (DRAM), etc. The main memory unit 1220 may include various non-volatile memory units contents (data) stored in which remain unchanged even when power is off, for example, a Phase Change Random Access Memory (PRAM), a Resistive Random Access Memory (RRAM), a Spin Transfer Torque Random Access Memory (STTRAM), a Magnetic Random Access Memory (MRAM), etc. The main memory unit 1220 may include various logic elements, for example, transistors formed over a semiconductor substrate, gates coupled to the transistors, flip-flops, etc., but also memory devices for storing data.

The auxiliary memory unit 1230 is a memory device for storing a program code or data. The auxiliary memory unit 1230 may store a large amount of information or data. The auxiliary memory unit 1230 operates at a lower speed than the main memory unit 1220. The auxiliary memory unit 1230 may include data storage systems, for example, a magnetic tape using a magnetic field, a magnetic disc, a laser disc using light, a magneto-optical disc using the magnetic disc and the laser disc, a Solid State Disc (SSD), a Universal Serial Bus (USB) memory, a Secure Digital (SD), a mini Secure Digital (mSD) card, a micro SD, a high-capacity Secure Digital High Capacity (SDHC), a memory stick card (MSC), a Smart Media (SM) card, a Multi Media Card (MMC), an Embedded MMC (eMMC), a Compact Flash (CF) card, etc. The auxiliary memory unit 1230 may include various logic elements, for example, transistors formed over a semiconductor substrate, gates coupled to the transistors, flip-flops, etc., but also memory devices for storing data.

The interface unit 1240 may be configured to exchange command and data between the system of this embodiment and an external device, and may be any of a keypad, a keyboard, a mouse, a speaker, a microphone, a display, a variety of Human Interface Devices (HIDs), a communication device, etc., which are configured to achieve data communication through a transmission line. The communication device may include a module coupled to a wired network and a module coupled to a wireless network.

The wired network module may include a Local Area Network (LAN), a Universal Serial Bus (USB), an Ethernet, a Power Line Communication (PLC), etc. The wireless network module may include an Infrared Data Association (IrDA), a Code Division Multiple Access (CDMA), a Time Division Multiple Access (TDMA), a Frequency Division Multiple Access (FDMA), a Wireless LAN, a Zigbee, a Ubiquitous Sensor Network (USN), a Bluetooth, a Radio Frequency Identification (RFID), a Long Term Evolution (LTE), a Near Field Communication (NFC), a Wireless Broadband Internet (Wibro), a High Speed Downlink Packet Access (HSDPA), a Wideband CDMA (WCDMA), a Ultra WideBand (UWB), etc., which are configured to achieve data communication without using a transmission line.

The system 1200 may include a through silicon via (TSV). TSVs are formed over a semiconductor substrate of the processor 1210, the main memory unit 1220, or the auxiliary memory unit 230, etc. so as to be coupled to various external devices so that data or signal transmission can be performed at high speed. Each of the processor 1210, the main memory unit 1220, the auxiliary memory unit 1230, etc. may include a plurality of TSVs. The TSV structure may include a TSV formed in a semiconductor substrate including a first-type impurity; and a first doping region including a second-type impurity, formed in the semiconductor substrate located below the TSV, and electrically coupled to the TSV. The processor 1210, the main memory unit 1220, the auxiliary memory unit 1230, etc. of the system 1200 according to the embodiment may include a PN junction (diode) formed by the first doping region and the semiconductor substrate. As a result, each of the processor 1210, the main memory unit 1220, the auxiliary memory unit 1230, etc. of the system 1200 may be configured to block an electric path between the TSV and the semiconductor substrate during a normal operation mode. In contrast, in a test mode, a current path is formed between the TSV and the semiconductor substrate through the PN junction in the test mode. In the test mode, whether there is a defect in the TSV structure. The defect may include a void of the TSV. Through such test, reliability of the system 1200 can be increased. The processor 1210, the main memory unit 1220, the auxiliary memory unit 1230, etc. of the system 1200 may be stacked through TSVs, such that they can be electrically coupled to each other.

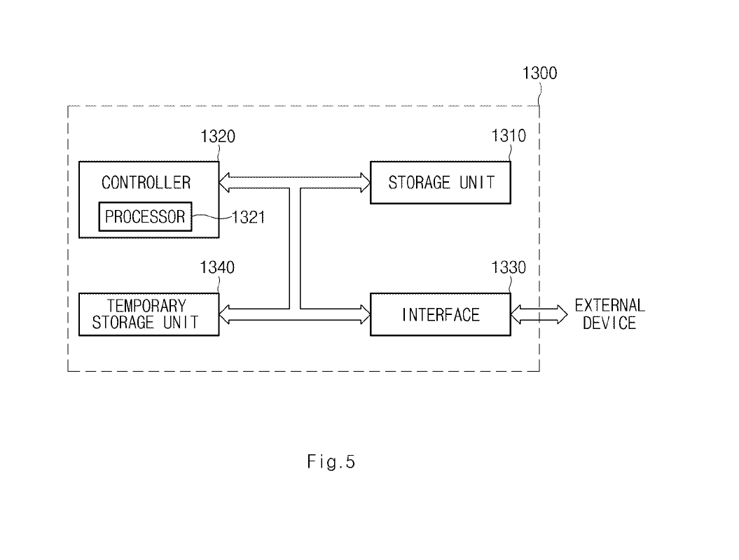

FIG. 5 is a block diagram illustrating a data storage system 1300 according to an embodiment.

Referring to FIG. 5, the data storage system 1300 may include a non-volatile storage unit 1310 for storing data, a controller 1320 for controlling the non-volatile storage unit 1310, and an interface 1330 coupled to an external device. The data storage system 1300 may be configured in the form of a disc, for example, a Hard Disk Drive (HDD), a Compact Disc Read Only Memory (CDROM), a Digital Versatile Disc (DVD), a Solid State Disc (SSD), and may also be configured in the form of a card, for example, a Universal Serial Bus (USB) memory, a Secure Digital (SD), a mini Secure Digital (mSD) card, a micro SD card, a high-capacity Secure Digital High Capacity (SDHC), a Memory Stick Card, a Smart Media (SM) card, a Multi Media Card (MMC), an Embedded MMC (eMMC), a Compact Flash (CF) card, etc.

The controller 1320 may control data exchange between the storage unit 1310 and the interface 1330. For this purpose, the controller 1320 may include a processor configured to calculate/process commands received through the interface 1330 from an external part of the data storage system 1300.

The interface 1330 may exchange commands and data between the data storage system 1300 and the external device. If the data storage system 1300 is configured in the form of a card, the data storage system 1300 may be used as an interface that is compatible with a Universal Serial Bus (USB) memory, a Secure Digital (SD) card, a mini Secure Digital (mSD) card, a micro SD card, a high-capacity Secure Digital High Capacity (SDHC), a memory stick card, a Smart Media (SM) card, a Multi Media Card (MMC), an Embedded MMC (eMMC), and a Compact Flash (CF) card. If the data storage system 1300 is configured in the form of a disc, the data storage system 1300 may be used as an interface that is compatible with an Integrated Device Electronics (IDE), a Serial Advanced Technology Attachment (SATA), a Small Computer System Interface (SCSI), External SATA (eSATA), a Personal Computer Memory Card International Association (PCMCIA), and a Universal Serial Bus (USB).

As an interface for an external device, a controller, and a system are gradually diversified and manufactured to have higher performance, the data storage system 1300 according to the embodiment may further include a temporary storage unit 1340 configured to efficiently perform data communication between the interface 1330 and the storage unit 1310. The data storage system 1300 may include a plurality of TSVs in a semiconductor substrate. The TSV structure may include a TSV formed in a semiconductor substrate including a first-type impurity; and a first doping region including a second-type impurity, formed in the semiconductor substrate located below the TSV, and electrically coupled to the TSV. The storage unit 1310, the controller 1320, or the temporary storage unit 1340 of the data storage system 1300 according to the embodiment may include a PN junction (diode) formed by the first doping region and the semiconductor substrate. As a result, the storage unit 1310, the controller 1320, or the temporary storage unit 1340 of the data storage system 1300 may be configured to prevent an electric path from being created between the TSV and the semiconductor substrate during a normal operation, while allowing the current path to form between the TSV and the semiconductor substrate through a PN junction. In the test mode, whether a defect exists in the TSV structure. The defect may include a void in the TSV. Through such test, reliability of the data storage system 1300 may be increased.

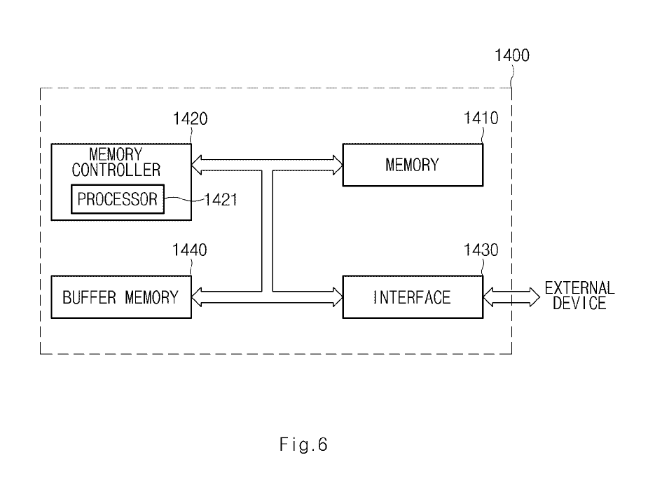

FIG. 6 is a block diagram illustrating a memory system 1400 according to an embodiment of the present invention.

Referring to FIG. 6, the memory system 1400 may include a non-volatile memory 1410 for storing data, a memory controller 1420 for controlling the non-volatile memory 1410, and an interface 1430 coupled to an external device. The memory system 1400 may be configured in the form of a card, for example, a Solid State Disc (SSD), a Universal Serial Bus (USB) memory, a Secure Digital (SD) card, a mini Secure Digital (mSD) card, a micro SD card, a Secure Digital High Capacity (SDHC), a memory stick card, a Smart Media (SM) card, a Multi Media Card (MMC), an embedded MMC (eMMC), a Compact Flash (CF) card, etc.

The memory 1410 for storing data may further include a non-volatile memory, for example, a Read Only Memory (ROM), a Nor Flash Memory, a NAND Flash Memory, a Phase Change Random Access Memory (PRAM), a Resistive Random Access Memory (RRAM), a Magnetic Random Access Memory (MRAM), etc. The memory 1410 serving as a semiconductor device may include various logic elements, for example, transistors formed over a semiconductor substrate, gates coupled to the transistors, flip-flops, etc. The memory 1410 may include various kinds of semiconductor devices to implement higher capacity.

The memory 1410 may include a plurality of TSVs in a semiconductor substrate. In the memory 1420, multiple semiconductor devices are stacked through TSVs, and are electrically coupled to each other. The TSV according to the embodiment may include a TSV formed in a semiconductor substrate including a first-type impurity; and a first doping region including a second-type impurity, formed in the semiconductor substrate and below the TSV, and electrically coupled to the TSV. Therefore, the memory 1410 according to the embodiment may include a PN junction (diode) formed by the first doping region and the semiconductor substrate. As a result, the memory 1410 may be configured to prevent an electric path from arising between the TSV and the semiconductor substrate in a normal operation mode. In contrast, in a test mode, a current path is allowed to arise between the TSV and the semiconductor substrate through the PN junction. In the test mode, it is tested whether a defect exists in the TSV structure. The defect may include a void in the TSV. By employing this test operation, reliability of the memory 1410 can be increased.

The memory controller 1420 may control data exchange between the memory 1410 and the interface 1430. For this purpose, the memory controller 1420 may include a processor 1421 configured to calculate/process commands received through the interface 1430 from an external part of the memory system 1400. The memory controller 1420 serving as a semiconductor device may include various logic elements, for example, transistors formed over a semiconductor substrate, gates coupled to the transistors, flip-flops, etc.

The interface 1430 may exchange commands and data between the memory system 1400 and the external device, may be compatible with a Universal Serial Bus (USB) memory, a Secure Digital (SD) card, a mini Secure Digital (mSD) card, a micro SD card, a high-capacity Secure Digital High Capacity (SDHC), a memory stick card, a Smart Media (SM) card, a Multi Media Card (MMC), an Embedded MMC (eMMC), and a Compact Flash (CF) card, and may include similar formats. The interface 1420 may be implemented as different types of interfaces as necessary.

To allow an interface for an external device, a memory controller, and a memory system to have higher performance, the memory system 1400 according to the embodiment may further include a buffer memory 1440. The buffer memory 1440 may be configured to efficiently perform the data input/output (I/O) operation between the interface 1430 and the memory 1410. The buffer memory 1440 for temporarily storing data may include the above-mentioned semiconductor device. The buffer memory 1440 may include various logic elements, for example, transistors formed over a semiconductor substrate, gates coupled to the transistors, flip-flops, etc. The buffer memory 1440 may include a combination of semiconductor devices to implement higher capacity. The buffer memory 1440 may include a plurality of TSVs formed in a semiconductor substrate. In the buffer memory 1440, multiple semiconductor devices are stacked through TSVs, and are electrically coupled to each other. The TSV according to the embodiment may include a TSV formed in a semiconductor substrate including a first-type impurity; and a first doping region including a second-type impurity, formed in the semiconductor substrate located below the TSV, and electrically coupled to the TSV. Therefore, the buffer memory 1440 according to the embodiment may include a PN junction (diode) formed by the first doping region and the semiconductor substrate. As a result, the buffer memory 1440 may be configured to prevent an electric path from arising between the TSV and the semiconductor substrate in a normal operation mode. In contrast, in a test mode, a current path can be formed between the TSV and the semiconductor substrate through a PN junction. During the test mode, a defect in the TSV structure such as a void of the TSV is inspected to increase reliability of the buffer memory 1440.

In addition, the buffer memory 1440 according to the embodiment may further include a volatile Static Random Access Memory (SRAM), a Dynamic Random Access Memory (DRAM), a non-volatile Phase Change Random Access Memory (PRAM), a Resistive Random Access Memory (RRAM), a Spin Transfer Torque Random Access Memory (STTRAM), a Magnetic Random Access Memory (MRAM), etc.

The memory system 1400 may include a through silicon via (TSV) formed in a semiconductor substrate of the memory controller 1420 to transmit/receive data to/from data various external devices at high speed. In the memory system 1400, the memory controller 1420, the memory 1410, the buffer memory 1440, etc. are stacked through TSVs, and are electrically coupled to each other. The TSV according to the embodiment may include a TSV formed in a semiconductor substrate including a first-type impurity; and a first doping region including a second-type impurity, formed in the semiconductor substrate located below the TSV, and electrically coupled to the TSV. Therefore, the memory controller 1420, etc. of the memory system 1400 according to the embodiment may include a PN junction (diode) formed by the first doping region and the semiconductor substrate. As a result, in a normal operation mode, the memory controller 1420, etc. of the memory system 1400 may prevent an electric path from being formed between the TSV and the semiconductor substrate. However, in a test mode, a current path is formed through a PN junction and test whether there is a defect in the TSV structure such as a void of the TSV, thereby providing a high-speed memory system 1400 having increased reliability.

The above exemplary embodiments are therefore to be construed in all aspects as illustrative and not restrictive

What is claimed is:

1. A semiconductor device comprising:
a through silicon via (TSV) formed in a semiconductor substrate including a first-type impurity; and
a first doping region formed in the semiconductor substrate below the TSV,
wherein the first doping region is doped with a second-type impurity and is configured to be selectively electrically coupled to the TSV.

2. The semiconductor device according to claim 1, wherein the first-type impurity includes P-type impurity.

3. The semiconductor device according to claim 1, wherein the second-type impurity includes N-type impurity.

4. The semiconductor device according to claim 1, further comprising:
a second doping region including the first-type impurity and configured to be electrically isolated from the TSV.

5. The semiconductor device according to claim 4, further comprising:
a power-supply circuit coupled to the second doping region.

6. The semiconductor device according to claim 1, further comprising:
a test circuit coupled to the TSV so as to be applied to a current or voltage through the TSV.

7. The semiconductor device according to claim 1, further comprising:
a data memory element electrically coupled to the TSV.

8. The semiconductor device according to claim 7, wherein the data memory element includes at least one of a capacitor, a floating gate, a resistance variation element, a magnetic variation element.

9. The semiconductor device according to claim 1, further comprising:
a data processing element electrically coupled to the TSV.

10. The semiconductor device according to claim 9, wherein the data processing element includes at least one of a central processing unit (CPU), a graphic processing unit, a digital signal processing (DSP) unit, and an electronic element capable of processing other data.

11. A method for detecting a defect of a semiconductor device comprising:
providing a power-supply circuit;
applying a current or voltage from the power-supply circuit to a test circuit through a PN junction and a through silicon via (TSV) in a semiconductor substrate;
applying the current or voltage to a gate of the test circuit; and
monitoring a current or voltage flowing toward a ground voltage (VSS) terminal.

12. The method according to claim 11, wherein the PN junction includes a first doping region and a second doping region.

13. The method according to claim 12, wherein the first doping region includes N-type impurity.

14. The method according to claim 12, wherein the first doping region includes N-type polysilicon.

15. The method according to claim 12, wherein the second doping region includes P-type impurity.

16. The method according to claim 12, wherein the second doping region includes P-type polysilicon.

17. The method according to claim 12, wherein the first doping region is formed below the TSV.

18. The method according to claim 11, wherein the power-supply circuit is coupled to the second doping region.
